(19) United States
(12) Patent Application Publication
(10) Pub. No.: US 2006/0060566 A1
(43) Pub. Date: Mar. 23, 2006

(54) Method and device for substrate etching with very high power inductively coupled plasma

(76) Inventor: Michel Puech, Metz-Tessy (FR)

Correspondence Address: SUGHRUE MION, PLLC, 2100 PENNSYLVANIA AVENUE, N.W., SUITE 800, WASHINGTON, DC, 20037, US

(21) Appl. No.: 10/516,455

(22) PCT Filed: Jul. 10, 2003
(86) PCT No.: PCT/FR03/02157

§ 371 Date: Dec. 3, 2004

(30) Foreign Application Priority Data
Jul. 11, 2002 (FR) 02/08729

(51) Int. Cl. C23F 1/00; H01L 21/302

(52) U.S. Cl. 216/67; 438/689

(57) ABSTRACT

According to the invention, etching is performed in a reaction chamber (1) by subjecting a substrate (16) biased by a bias generator (15) to a plasma generated by a plasma source (4) contained in a leakproof wall (5) of dielectric material surrounded by an inductive coupled antenna (6) powered by a radiofrequency generator (7). Control means (13) control solenoid valves (12a, 12b, 12c) and the radiofrequency generator (7) so as to produce a prior step of establishing the plasma excitation power progressively, during which step an inert gas such as argon or nitrogen is injected into the reaction chamber (1), and the power delivered by the radiofrequency generator (7) is raised progressively until it reaches a nominal power. This avoids applying thermal shock to the leakproof wall (5) of dielectric material that might otherwise destroy the wall, thus making it possible to plasma excitation powers that are greater than 3000 W.

### TECHNICAL FIELD OF THE INVENTION

The present invention relates to methods and apparatuses for etching substrates, for example in the reactors used for implementing micromachining or etching methods on a silicon substrate.

When a silicon substrate is etched in a plasma reactor, the sequences are as follows:
after the substrate has been inserted and positioned on a sample carrier contained in a reaction chamber, the etching gas(es), such as a fluorine-containing gas like SF₆, is/are introduced at a pre-established rate;
an appropriate pressure is established in the reaction chamber by means of a pump unit and a pressure servo-control system, and said pressure is maintained; and
once the pressure has stabilized, the gas in the reaction chamber is excited by an excitation electromagnetic wave for generating a plasma; simultaneously, the substrate on the sample carrier is biased to accelerate the ions which then bombard the surface of the substrate that is being etched.

In micromachining applications, it is desired to etch the silicon as quickly as possible. Amongst the parameters that are accessible for controlling etching speed, the parameters having the most influence are the following:
the partial pressure of halogen-containing gas ions such as SF₆;
the power of the electromagnetic wave for exciting the gas.

The power of the excitation electromagnetic wave serves to ionize and dissociate the halogen-containing gas molecules such as SF₆ so as to generate fluorine atoms. On reaching the surface of the silicon substrate, these fluorine atoms react therewith to form gaseous molecules in application of the reaction:
Si(s)+4F(g)→SiF₄(g)

Etching thus consists in taking atoms of silicon from the substrate which are transformed by the reaction into a gas SiF₄, which gas is then removed from the reaction chamber by the pump means.

It will be understood that the speed at which the silicon is etched is directly proportional to the pressure of atomic fluorine, and thus to the dissociation ratio of the halogen-containing gas molecules such as SF₆.

Amongst the various types of plasma source, the following sources are known: reactive ion etching (RIE) sources, electron cyclotron resonance (ECR) sources, and inductively-coupled plasma (ICP) sources. The sources that present the greatest dissociation ratio under high pressure conditions are ICP sources, thereby making it possible to have both a high dissociation ratio and a high partial pressure of atoms from the halogen-containing gas such as SF₆ in the reaction chamber.

It is therefore natural to use an ICP source in order to increase the speed at which the silicon is etched.

ICP type plasma sources are all constituted by two main elements:
a leakproof wall of dielectric material which closes the reaction chamber in leakproof manner; and
an antenna made of electrically-conductive material such as copper, surrounding or surmounting the leakproof wall made of dielectric material; the antenna is connected at one of its ends to the electrical ground of the equipment, and at its other end to a radiofrequency (RF) power generator via an automatic impedance matcher.

The leakproof wall of dielectric material is connected to the remainder of the wall of the reaction chamber, which is generally made of metal, via gaskets that are generally made of polymer type materials. Such materials have maximum working temperatures in continuous utilization that do not exceed 150° C. As a result, the zone of the reaction chamber wall that is close to the gaskets is cooled.

During a process of etching a substrate such as silicon, the quality of the etching depends on all of the etching parameters being adjusted to specific values at all times, and in particular the pressure of the etching gas, and also the power of the excitation electromagnetic wave transmitted to the gas in order to generate the plasma. The etching sequences are run one after another over a time interval of the order of a few milliseconds (ms).

Consequently, at the plasma source, there is a situation where it is necessary to produce quasi-instantaneous inductive coupling of the nominal RF power to the plasma through the leakproof wall of dielectric material.

Until now, quasi-instantaneous inductive coupling of the excitation electromagnetic wave has been possible up to powers of about 2000 watts (W), by using leakproof walls made of dielectric material that withstand high temperatures. Alumina Al₂O₃ has been used with success.

Nevertheless, such a material does not enable quasi-instantaneous conductive coupling to be achieved with an excitation electromagnetic wave at a power greater than a maximum of about 3000 W, since otherwise the plasma source is destroyed quasi-instantaneously: the leakproof wall of dielectric material cracks, thereby returning the inside of the etching reactor to atmospheric pressure, and possibly leading to the assembly imploding, and thus being destroyed.

Thus, at present, there is no solution that enables very high powers to be coupled in quasi-instantaneous manner through a dielectric material such as alumina.

### SUMMARY OF THE INVENTION

An object of the present invention is to avoid the drawbacks of prior art structures and methods for etching a substrate by an inductively-coupled plasma, by making it possible to couple RF powers up to 5000 W through a dielectric material such as alumina.

Simultaneously, the invention seeks to conserve good quality for the etching, avoiding the use of etching steps in which the parameters are not maintained precisely at their nominal values.

The idea on which the invention is based is to reduce the thermal shock to the dielectric material constituting the plasma source, by coupling the power of the excitation electromagnetic wave gradually. A power rise ramp is thus used with the slope of the ramp being sufficiently gentle to avoid creating a destructive thermal shock.

However, since etching quality and performance depend on the values of machine parameters such as RF power, it is not possible to envisage triggering the etching plasma and then causing power to rise progressively while the substrate is in position on the biased sample carrier: that would lead throughout the power rise stage to plasma conditions that are extremely variable and harmful to obtaining good etching performance.

According to the invention, power is raised progressively, but in the presence of an inert gas such as nitrogen or argon, so that there is no reaction between said gas and the silicon sample.

The sole function of the inert gas is to enable a plasma to be generated which, under the effect of the progressive rise in power, serves to heat the dielectric material progressively, thereby bringing it to its working temperature corresponding to the maximum power that is used throughout the step of etching by means of a plasma of reagent gas.

After this step of raising the temperature of the dielectric material by means of a plasma of inert gas, it is possible to stop injecting the inert gas and to switch over instantly to a halogen-containing reagent gas such as SF₆ in order to perform etching proper.

To achieve these objects, and others, the invention provides a method of etching a substrate by an inductively-coupled plasma, in which the substrate is placed in a reaction chamber, an atmosphere of an appropriate gas is established in the reaction chamber at a suitable operating pressure, the substrate is biased, and the gas in the reaction chamber is excited by a radiofrequency excitation electromagnetic wave passing through a leakproof wall of dielectric material in order to generate a plasma; according to the invention, the method includes a prior step of establishing the power of the plasma excitation electromagnetic wave progressively, during which step a gas that is inert for the substrate is injected into the reaction chamber and the power of the plasma excitation electromagnetic wave is raised progressively until the appropriate nominal power is reached, thereby forming an inert gas plasma which progressively heats up the leakproof wall of dielectric material, after which active gas is injected into the reaction chamber in order to replace the inert gas and undertake active steps of etching by means of the plasma of active gas.

Preferably, the progressive increase in the plasma excitation power is programmed so as to ensure that the thermal shock applied to the leakproof wall of dielectric material by the inert gas plasma remains below a wall-destroying threshold.

When possible, the prior step of progressively establishing the plasma excitation power is undertaken solely at the beginning of reaction chamber operation after a period of inactivity, and is followed by alternating active etching steps during which the temperature of the leakproof wall of dielectric material remains in a range of values that is sufficiently narrow to avoid any destructive thermal shock being applied to the leakproof wall of dielectric material.

The active etching steps may comprise a succession of etching steps using a fluorine-containing gas such as SF₆, and passivation steps using a of etching passivation gas such as CₓF_{y}.

The invention also provides apparatus for etching substrates by an inductively-coupled plasma implementing the method as defined above, the apparatus comprising a reaction chamber surrounded by a leakproof wall, the reaction chamber having substrate support means and being in communication with an inductively-coupled plasma source having a leakproof wall of dielectric material and an inductive coupling antenna powered by a radiofrequency generator, the reaction chamber being connected via a vacuum line to pump means for establishing and maintaining an appropriate vacuum inside the reaction chamber, the reaction chamber being connected via an inlet line to a process gas source; according to the invention:
the process gas source comprises an inert gas source, at least one active gas source, and distribution means controlled by control means to introduce the appropriate gas into the reaction chamber;
the radiofrequency generator has means for adjusting its radiofrequency power under the control of the control means; and
the control means include a control program with a prior sequence of establishing power, during which:
   a) the control means control the distribution means to introduce an inert gas into the reaction chamber;
   b) the control means cause the radiofrequency power control means of the radiofrequency generator to produce radiofrequency energy that increases progressively until reaching the nominal power; and
   c) thereafter the control means control the distribution means to replace the neutral gas in the reaction chamber with an active gas.

### BRIEF DESCRIPTION OF THE DRAWINGS

Other objects, characteristics, and advantages of the present invention appear from the following description of particular embodiments, given with reference to the accompanying figures, in which:

FIG. 1 is a diagrammatic view showing the general structure of etching apparatus in an embodiment of the present invention; and

FIG. 2 is a timing diagram showing the operation of the main members of the FIG. 1 apparatus, diagram a) showing variation in the plasma excitation power; diagram b) showing the feed of inert gas to the reaction chamber; diagram c) showing the feed of etching gas to the reaction chamber; diagram d) showing the feed of passivation gas to the reaction chamber; and diagram e) showing the bias applied to the substrate for etching.

### DESCRIPTION OF PREFERRED IMPLEMENTATIONS

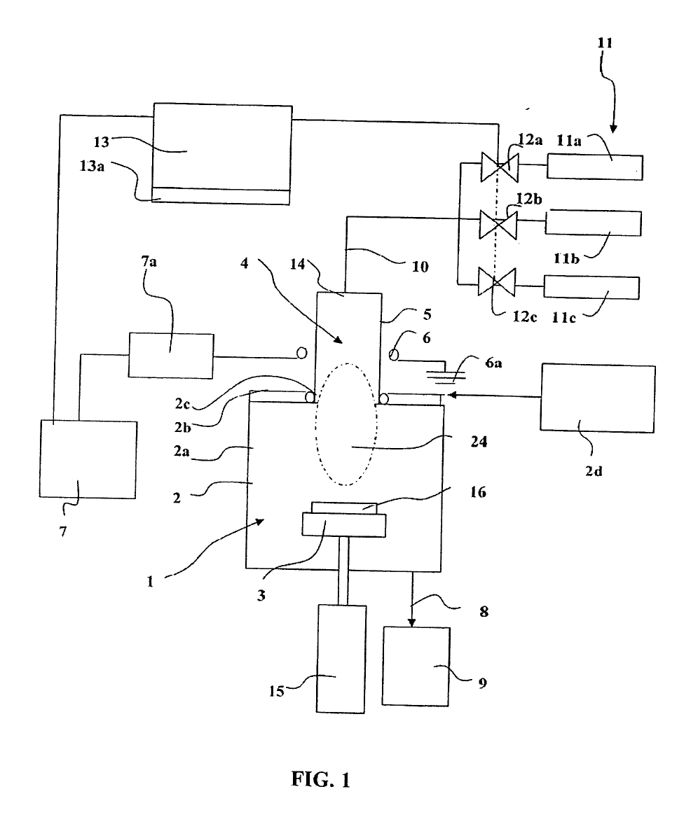

Reference is made initially to the apparatus shown in FIG. 1. There can be seen a reaction chamber 1 surrounded by a leakproof wall 2. The reaction chamber 1 contains substrate support means 3 suitable for receiving and holding a substrate 16 for etching. The reaction chamber 1 is in communication with an inductively-coupled plasma source 4 constituted by a leakproof wall 5 of dielectric material associated with an inductive coupling antenna 6 powered by an RF generator 7 via an impedance matcher 7a.

The reaction chamber 1 is connected by a vacuum line 8 to pump means 9 for establishing and maintaining a suitable vacuum inside the reaction chamber 1. The reaction chamber 1 is connected by an inlet line 10 to a source of process gas 11.

In the embodiment shown, the leakproof wall 2 of the reaction chamber has a peripheral portion 2a which is connected to an inlet front portion 2b which is itself open in order to communicate with an inlet tube constituting the plasma source 4.

This plasma source 4, in the embodiment shown, is constituted by a leakproof wall 5 of dielectric material and of tubular shape, and the inductive coupling antenna 6 is a coaxial turn of electrically conductive material disposed around the tubular wall, and connected firstly to apparatus ground 6a and secondly to the outlet of the impedance matcher 7a.

The inductive coupling antenna 6 is placed around the central portion of the tubular leakproof wall 5 of dielectric material, itself constituted by alumina Al₂O₃.

To connect the tubular leakproof wall 5 of dielectric material with the inlet front portion 2b of the reaction chamber 1, which portion 2b is generally made of metal, a sealing gasket 2c is provided. Cooling means 2d are also provided to enable the inlet front portion 2b and the sealing gasket 2c to be cooled.

The substrate 16 held on the substrate support means 3 is biased by a bias generator 15 in conventional manner.

The process gas source 11 comprises an inert gas source 11a, and at least one source of active gas. For example, a first active gas source 11b is provided containing a fluorine-containing gas such as SF₆ for etching purposes, and a second active gas source 11c is provided containing a passivation gas such as C₄F₈.

Distribution means serve to control the introduction of an appropriate gas into the reaction chamber 1. The distribution means comprises solenoid valves 12a, 12b, and 12c each connected in series between the outlet of a corresponding gas source 11a, 11b, or 11c, and an inlet 14 to the plasma source 4.

The RF generator 7 has means for adjusting its RF power, under the control of control means 13. Similarly, the distribution means 12a, 12b, and 12c are controllable by the control means 13.

Control means 13 are provided, e.g. a micro-controller with inlet/outlet members, and associated with a controlling program, that is adapted to control the distribution means having solenoid valves 12a-12c and the RF generator 7.

The control means 13 have a control program 13a with a prior sequence for running up to power during which:

a) the control means 13 cause the distribution means to open the inert gas valve 12a so as to introduce an inert gas such as nitrogen N₂ or argon into the reaction chamber 1;

b) the control means 13 cause the RF power adjustment means of the RF generator 7 to produce RF energy which increases progressively until it reaches nominal power PN, so as to produce a plasma 24 in the plasma source 4 in order progressively to raise the temperature of the leakproof wall 5 of dielectric material of the plasma source; and

c) once the leakproof wall 5 has been heated sufficiently, the control means 13 cause the distribution means to close the inert gas valve 12a and open a valve 12b or 12c for delivering active gas. In practice, the etching gas valve 12b and the passivation gas valve 12c are opened sequentially so as to introduce the active gases into the reaction chamber 1, and the control means 13 simultaneously control the means for adjusting the RF power of the RF generator 7 so as to produce the plasma 24 that is appropriate for the etching steps and for the passivation steps.

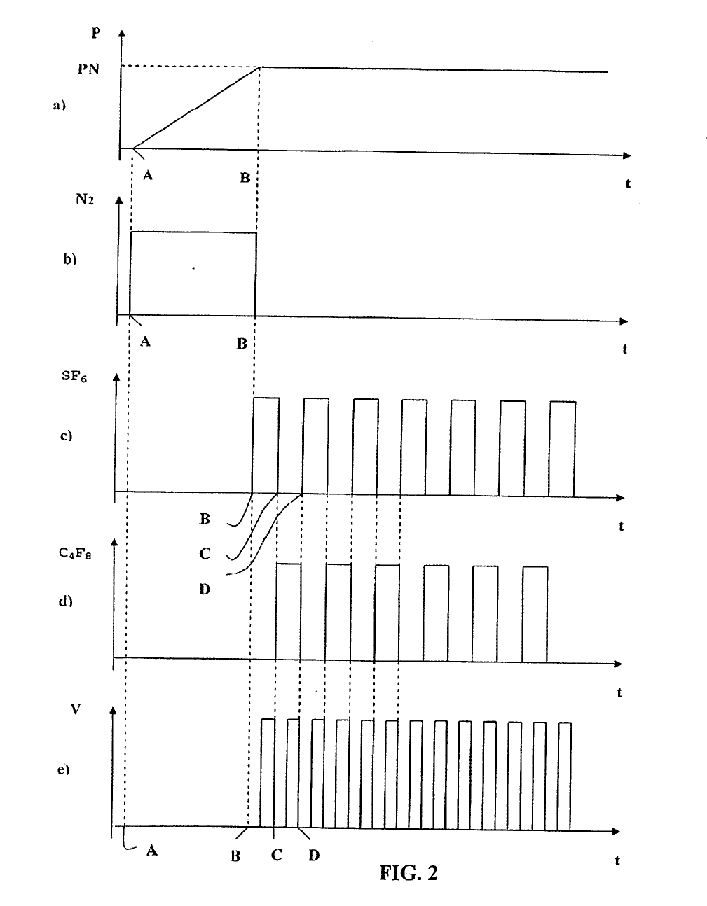

Reference is now made to FIG. 2 which shows the steps in an etching method in an implementation of the invention.

After placing the substrate 16 (FIG. 1) in the reaction chamber 1, an atmosphere of inert gas such as nitrogen N₂ or argon is established in the reaction chamber: at instant A, diagram b) indicates the presence of nitrogen during a first step that continues unit instant B. During this step, the pump means 9 establish and maintain a suitable pressure inside the reaction chamber 1, which pressure is selected to enable a plasma 24 to be established properly. During this step, the substrate 16 is not biased, as can be seen from diagram e) in FIG. 2: the bias voltage V is absent throughout the step between instants A and B. During this same step, the plasma excitation power is established progressively, as shown in diagram a) of FIG. 2, e.g. by increasing power in linear manner between instants A and B until the nominal power PN is reached at instant B.

At instant B, or after an additional delay determined to ensure that the leakproof wall 5 is sufficiently heated, the introduction of inert gas such as nitrogen or argon is interrupted, as represented by way of example in diagram b) which shows the end of the presence of nitrogen as from instant B.

At the same instant B, or after the above-mentioned additional delay, a halogen-containing etching gas such as SF₆ is introduced into the reaction chamber 1 and the presence of that gas is maintained during a step BC of duration that is appropriate as a function of the desired etching process. During this step, the substrate is biased by a voltage V as shown in diagram e), with the bias voltage possibly being established with a suitable delay relative to the presence of etching gas SF₆ becoming established. Thereafter, at instant C, the etching gas SF₆ is replaced by a passivation gas such as C₄F₈, and diagram c) shows the disappearance of SF₆ while diagram d) shows the appearance of C₄F₈ and shows that it is maintained until instant D. During this step CD, the passivation gas causes polymer to be deposited on the surfaces of the substrate. Etching steps and passivation steps are subsequently alternated, as shown in the diagrams, with the substrate being biased each time to attract the plasma 24, and with the plasma excitation power being maintained at a suitable value that may be close to the nominal value PN.

Thus, the prior step of progressively establishing the plasma excitation power is undertaken only at the beginning of operation of the reaction chamber 1 after it has been inactive for some length of time, and it is then followed by active steps of etching, e.g. alternating etching steps and passivation steps, during which the temperature of the leakproof wall 5 of dielectric material remains in a range of values that is sufficiently narrow to avoid any thermal shock that might destroy the leakproof wall 5 of dielectric material.

During the prior step of progressively establishing the plasma excitation power, between instants A and B, the power rise slope as shown in diagram a) is selected to be sufficiently shallow to avoid any risk of the leakproof wall 5 of dielectric material being destroyed by the plasma of inert gas.

By using an inert gas, such as nitrogen N₂ or argon, it is ensured that the inert gas plasma 24 does not act on the substrate 16 that is to be etched, thereby concerning etching of good quality. Preferably during this step, the substrate 16 is also not biased, so as to avoid the substrate 16 being bombarded by the plasma.

By using the means of the invention, it is possible without destroying the plasma source 4 and its leakproof wall 5 of dielectric material, to establish RF power greater than 3000 W, thereby enabling etching to be performed at a higher speed. Satisfactory tests have been undertaken with RF powers up to 5000 W, passing through a dielectric material such as alumina.

The invention is not limited to the embodiments explicitly described above, but it includes various variants and generalizations that are within the competence of the person skilled in the art.

1. A method of etching a substrate (16) by an inductively-coupled plasma (24), in which the substrate (16) is placed in a reaction chamber (1), an atmosphere of an appropriate gas is established in the reaction chamber (1) at a suitable operating pressure, the substrate (16) is biased, and the gas in the reaction chamber (1) is excited by a radiofrequency excitation electromagnetic wave passing through a leakproof wall (5) of dielectric material in order to generate a plasma (24), which method is characterized in that it includes a prior step of establishing the power of the plasma excitation electromagnetic wave progressively, during which step a gas that is inert for the substrate is injected into the reaction chamber (1) and the power of the plasma excitation electromagnetic wave is raised progressively until the appropriate nominal power is reached, thereby forming an inert gas plasma (24) which progressively heats up the leakproof wall (5) of dielectric material, after which active gas is injected into the reaction chamber (1) in order to replace the inert gas and undertake active steps of etching by means of the plasma (24) of active gas.

2. A method according to claim 1, characterized in that the progressive increase in the plasma excitation power is programmed so as to ensure that the thermal shock applied to the leakproof wall (5) of dielectric material by the inert gas plasma (24) remains below a wall-destroying threshold.

3. A method according got claim 1, characterized in that the prior step of progressively establishing the plasma excitation power is undertaken solely at the beginning of reaction chamber operation after a period of inactivity, and is followed by alternating active etching steps (BC; CD) during which the temperature of the leakproof wall (5) of dielectric material remains in a range of values that is sufficiently narrow to avoid any destructive thermal shock being applied to the leakproof wall (5) of dielectric material.

4. A method according to claim 1, characterized in that the active etching steps comprise a succession of etching steps (BC) using a fluorine-containing gas such as SF₆, and passivation steps (CD) using a of etching passivation gas such as CₓF_{y}.

5. Apparatus for etching substrates (16) by an inductively-coupled plasma, the apparatus implementing a method according to any one of claims 1 to 4, and comprising a reaction chamber (1) surrounded by a leakproof wall (2), the reaction chamber (1) having substrate support means (3) and being in communication with an inductively-coupled plasma source (4) having a leakproof wall (5) of dielectric material and an inductive coupling antenna (6) powered by a radiofrequency generator (7), the reaction chamber (1) being connected via a vacuum line (8) to pump means (9) for establishing and maintaining an appropriate vacuum inside the reaction chamber (1), the reaction chamber (1) being connected via an inlet line (10) to a process gas source (11), the apparatus being characterized in that:
the process gas source (11) comprises an inert gas source (11a), at least one active gas source (11b, 11c), and distribution means (12a, 12b, 12c) controlled by control means (13) to introduce the appropriate gas into the reaction chamber (1);
the radiofrequency generator (7) has means for adjusting its radiofrequency power under the control of the control means (13); and
the control means (13) include a control program (13a) with a prior sequence of establishing power, during which:
a) the control means (13) control the distribution means (12a, 12b, 12c) to introduce an inert gas into the reaction chamber (1);
b) the control means (13) cause the radiofrequency power control means of the radiofrequency generator (7) to produce radiofrequency energy that increases progressively until reaching the nominal power (PN); and
c) thereafter the control means (13) control the distribution means (12a, 12b, 12c) to replace the neutral gas in the reaction chamber (1) with an active gas.

6. Apparatus according to claim 5, characterized in that the distribution means (12a, 12b, 12c) comprise solenoid valves each connected in series between a respective corresponding gas source outlet (11a, 11b, 1c) and an inlet (14) to the plasma source (4).

7. Apparatus according to claim 5, characterized in that it includes a source (11a) of inert gas such as nitrogen (N₂) or argon, a source (11b) of an etching gas such as SF₆, and a source (11c) of a passivation gas such as C₄F₈.

8. Apparatus according to claim 5, characterized in that the leakproof wall (5) of dielectric material of the plasma source (4) is made of alumina Al₂O₃.

9. Apparatus according to claim 5, characterized in that the leakproof wall (5) of dielectric material of the plasma source (4) is of tubular shape, and the inductive coupling antenna (6) is a coaxial turn placed around the tubular wall.

10. Apparatus according to claim 5, characterized in that the leakproof wall (2) of the reaction chamber (1) has a peripheral portion (2a) connected to an inlet front portion (2b) that is itself open to communicate with an inlet tube constituting the plasma source (4), the inlet front portion (2b) being connected to the leakproof wall (5) of dielectric material by means of a sealing gasket (2c), together with cooling means (2d) for cooling the inlet front portion (2b) and the sealing gasket (2c).
